(19) United States
(12) Patent Application Publication
(10) Pub. No.: US 2006/0270182 A1
(43) Pub. Date: Nov. 30, 2006

(54) MANUFACTURING PROCESS OF SEMICONDUCTOR DEVICE AND SEMICONDUCTOR DEVICE

(75) Inventors: Takahisa AKIBA, Suwa-shi, Nagano-ken (JP); Taishi FUKIDA, Suwa-shi, Nagano-ken (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/382,183

(22) Filed: May 8, 2006

(30) Foreign Application Priority Data
May 27, 2005 (JP) 2005-155004

(51) Int. Cl. H01L 29/76; H01L 21/76

(52) U.S. Cl. 438/424; 257/288

(57) ABSTRACT

A manufacturing process of a semiconductor device, includes: forming a ground oxide film, which includes over a well region of a first conductive type, on a silicon semiconductor substrate; forming a nitride film over the ground oxide film; forming a mask pattern by selectively etching the nitride film and the ground oxide film; forming a trench by etching the semiconductor substrate according to the mask pattern; wet etching to retreat an edge part of the ground oxide film; oxidizing a surface inside the trench through a dry oxidation atmosphere at a temperature of 1,030 to 1,070° C.; annealing at a temperature higher than the oxidation; embedding an insulating film inside the trench; leveling out the insulating film; removing the mask pattern; removing a remaining film of the ground oxide film; forming a pre-oxide film on the semiconductor substrate; forming on the first conductive type region an impurity region of a second conductive type with a depth crossing the insulating film; etching to eliminate the pre-oxide film, and, at the same time, to make a round shape surface of an upper part of the trench exposed; forming a gate insulating film on the first conductive type region such that the edge part side may be placed from over the edge part of the impurity region of the second conductive type to over the edge part of the insulating film; and forming a gate electrode on the gate insulating film.

### BACKGROUND OF THE INVENTION

1. Technical Field

The invention relates to a manufacturing process of a semiconductor device and more particularly to a manufacturing process of a semiconductor device and a semiconductor device having a high voltage-resistant MOS element using a trench element separation technique in a semiconductor integrated circuit calling for microminiaturization.

2. Related Art

In a driver IC used for a liquid crystal device and the like, there is constituted a high voltage-resistant MOS transistor having in its drive output section a thick gate insulating film operable at a supply voltage exceeding 10V and a voltage resistance between a source and a drain (drain voltage resistance).

The high voltage-resistant MOS transistor has an offset gate structure to secure high drain voltage resistance. The offset structure is accompanied by a trench element separation film used in a mixedly loaded logic section (CMOS), that is, forming a trench between gate-drain electrodes, along which a low-concentration drift region is provided (for example, Japanese Unexamined Patent Publication No. 2001-15734).

Japanese Unexamined Patent Publication No. 2001-15734 (page 4, FIG. 2-FIG. 4) is an example of related art.

In a case where a trench structure is used for the offset structure of the high voltage-resistant MOS transistor it is feared that an insufficient film thickness of the gate insulating film of an end part of an active section may cause a decrease in reliability. For example, suppose that the trench as a whole is embedded in an oxide film as a trench separation film. Thereafter, a gate oxide film is formed on a silicon substrate through an oxidation process. However, the end part of the active section is prevented from supplying silicon due to the trench separation film (oxidation film), so that the gate oxide film of insufficient thickness tends to be produced. As a result, a gate oxide film portion not reaching a desired film thickness exists, which is feared to become an element with insufficient voltage resistance.

### SUMMARY

An advantage of some aspects of the invention is to provide a manufacturing process of a semiconductor device and a semiconductor device having good voltage resistance by securing a desired thickness of the gate oxide film even on an end part of an active section.

According to a first aspect of the invention, a manufacturing process of a semiconductor device includes: forming a ground oxide film, which covers over a well region of a first conductive type, on a silicon semiconductor substrate; forming a nitride film over the ground oxide film; forming a mask pattern by selectively etching the nitride film and the ground oxide film; forming a trench by etching the semiconductor substrate according to the mask pattern; wet etching to retreat an edge part of the ground oxide film; oxidizing a surface inside the trench through a dry oxidation atmosphere at a temperature of 1,030 to 1,070° C.; annealing at a temperature higher than the oxidation; embedding an insulating film inside the trench; leveling out the insulating film; removing the mask pattern; removing a remaining film of the ground oxide film; forming a pre-oxide film on the semiconductor substrate; forming on the first conductive type region an impurity region of a second conductive type with a depth crossing the insulating film; etching to eliminate the pre-oxide film, and, at the same time, to make a round shape surface of an upper part of the trench exposed; forming a gate insulating film on the first conductive type region such that the edge part side may be placed from over the edge part of the impurity region of the second conductive type to over the edge part of the insulating film; and forming a gate electrode on the gate insulating film.

According to a manufacturing process of a semiconductor device in accordance with the invention, a retreat of the ground oxide film by wet etching affects a change in shape of an upper edge part in the trench. Consequently, the thickness of the ground oxide film is critical. Further, when oxidizing the inside surface of the trench, oxidation at over 1,000° C. aids in forming a superior quality insulator.

Further, annealing at a temperature higher than the oxidation process contributes to relieving stress. The pre-oxide film is made to be thin enough to make it controllable for enhancing uniformity inside the surface. If it is made as thick as the ground oxide film, it is easy to handle when removing it since control can be referred to.

When completely removing the pre-oxide film, the surface of the round shape of the upper part of the trench is exposed by over etching. This enables supply of silicon to the upper edge part of the trench to increase. The gate insulating film becomes such that the extreme tapering is eliminated at its edge part to make its thickness closer to an average thickness of the central part.

In a manufacturing process of a semiconductor device according to the invention, the well region is a high voltage-resistant well region for a high voltage-resistant device and the thickness of its edge part side includes satisfying more than 70% with respect to the average thickness in the vicinity of the central part. Since silicon necessary for oxidation is exposed in a gentle round shape at the upper edge part of the trench, film loss at the end part of the gate insulating film can be considerably held down.

Further, in a manufacturing process of a semiconductor device According to the invention, the ground oxide film includes being formed for a target of 10 nm in film thickness. The retreat of the ground oxide film through the wet etching process affects a change in shape of the upper edge part at the trench. Consequently the thickness of the ground oxide film is critical. By making the ground oxide film approx. 10 nm thick, a more gentle round shape of the upper edge part of the trench can be realized.

According to a preferred aspect of the invention, a manufacturing process of a semiconductor device includes: forming a first well region of the first conductive type on a silicon semiconductor substrate; forming the ground oxide film which includes over the first well region; forming a nitride film for a mask on the ground oxide film; forming a mask pattern by selectively etching the nitride film and the ground oxide film; forming a trench by etching the semiconductor substrate according to the mask pattern; wet etching to retreat an edge part of the ground oxide film; oxidizing a surface inside the trench through a dry oxidation atmosphere at a temperature of 1,030 to 1,070° C.; annealing at a temperature higher than the oxidation; embedding an insulating film inside the trench; leveling out the insulating film through chemical and mechanical polishing; removing the mask pattern; removing a remaining film of the ground oxide film; forming a pre-oxide film on the semiconductor substrate having a thickness of 10 nm±0.5 nm; forming on the first conductive type region an impurity region of a second conductive type with a depth crossing the insulating film; etching to remove completely the pre-oxide film, and at the same time, to make a round shape surface of an upper part of the trench; forming a first gate insulating film on the first conductive type region such that at least the edge part side may be placed from over the edge part of the impurity region of the second conductive type to over the edge part of the insulating film; forming a second well region of the first conductive type or the second conductive type at a preset part of the semiconductor substrate other than the first well region; forming a second gate insulating film with less film thickness than the first gate insulating film on the semiconductor substrate in the second well region; forming the first gate electrode and the second gate electrode respectively on the first gate insulating film and the second gate insulating film; and forming an impurity region of an opposite conductive type to the second well region on both sides of the semiconductor substrate with the second gate electrode in between.

In a manufacturing process of a semiconductor device according to the invention, the retreat of the ground oxide film by wet etching affects a change in shape of an upper edge part in the trench. Consequently, the thickness of the ground oxide film is critical. Further, when oxidizing the inside surface of the trench, oxidation at over 1,000° C. aids in forming a superior quality insulator.

Furthermore, annealing at a temperature higher than the oxidation process contributes to relieving stress. For enhancing uniformity inside the surface, the pre-oxide film is formed to make it thin enough to be controllable so that the thickness of 10 nm±0.5 nm is attained. If it is made as thick as the ground oxide film, it is easy to handle when removing it since control can be referred to.

When completely removing the pre-oxide film, the surface of the round shape of the upper part of the trench is made to be exposed by over etching. This enables supply of silicon to the upper edge part of the trench to increase. The first gate insulating film becomes such that the extreme tapering is eliminated at its edge part to make its thickness closer to an average thickness of the central part. After formation of the first gate insulating film, a second well region, and a second insulating film are formed as other devices. The first electrode and the second electrode can be formed using the same process.

It should be noted that a manufacturing process of a semi-conductor device according to the invention can constitute a semiconductor device of high reliability by including either of the following features.

The ground oxide film includes being formed for a target of 10 nm in film thickness. Oxidizing the surface inside the trench includes oxidation processing time so that the inside wall of the trench becomes an oxide film approx. 30 nm thick.

The insulating film is a plasma silicon oxide film and includes being made into a film through high density plasma.

While the second gate insulating film is normally used for voltage resistance, the first gate insulating film is used for high voltage resistance. The first gate insulating film includes its edge part side thickness satisfying more than 70% with respect to the average thickness in the vicinity of the central part.

According to another aspect of the invention, a semiconductor device includes: the first and the second insulating films embedded in trenches mutually set apart from each other in a well region of the first conductive type in the silicon semiconductor substrate; a first impurity region of the second conductive type formed at a depth crossing the first insulating film on the well region and a second impurity region of the second conductive type formed at a depth crossing the second insulating film on the well region: a gate insulating film, which includes over a channel part of a surface of the well region in between the first and the second impurity regions with its both ends connected to one edge part of the first insulating film and one edge part of the second insulating film, an edge part side thickness satisfying more than 70% with respect to an average thickness in the vicinity of the central part; a gate electrode formed on the gate insulating film; and a source diffusion layer, which is formed on the first impurity region in the vicinity of the other edge part side of the first insulating film, and a drain diffusion layer, which is formed on the second impurity region in the vicinity of the other edge part side of the second insulating film, both layers being of the second conductive type of higher concentration than the first and the second impurity regions.

According to a semiconductor device in accordance with the invention, the gate insulating film has its both ends connected to one edge part of the first insulating film and one edge part of the second insulating film, an edge part side thickness satisfying more than 70% with respect to the average thickness in the vicinity of the central part. This enables a high voltage-resistant device of reliability, in which a decrease in thickness of the gate insulating film is restrained, to be realized.

### BRIEF DESCRIPTION OF THE DRAWINGS

The invention will be described with reference to the accompanying drawings, wherein like numbers refer to like elements.

FIG. 1 presents each sectional view showing work on a principal part of a manufacturing process of a semiconductor device according to one embodiment.

FIG. 2 is an enlarged view of a trench part relating to FIG. 1B.

FIG. 3 is an enlarged view showing a status of a gate insulating film of an end part of an active section relating to FIG. 1F.

FIG. 4 shows each sectional view showing work on forming a thin film transistor for normal voltage resistance of a logic section.

### DESCRIPTION OF THE EMBODIMENT

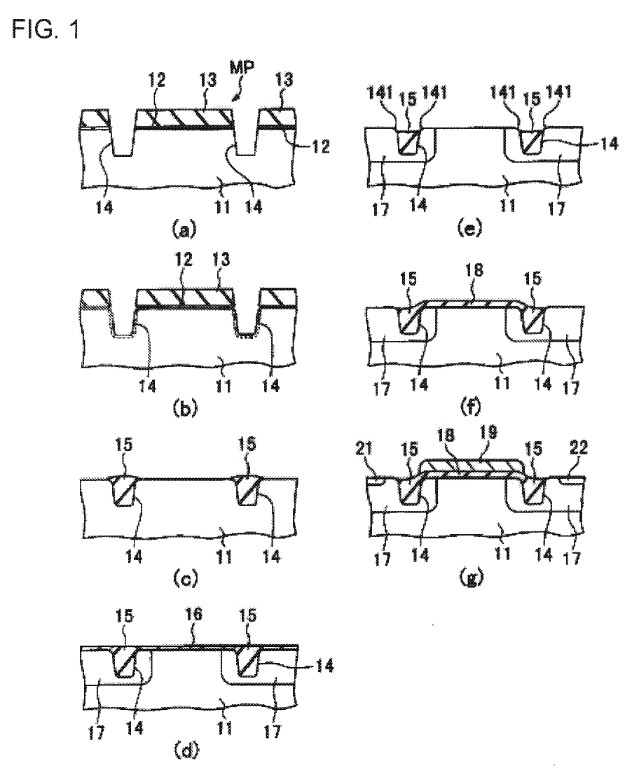

FIGS. 1A to 1G are respective sectional views showing a principal part of a manufacturing process of a semiconductor device according to one embodiment of the invention in terms of flow of work. The following manufacturing process is employed in case of constituting a high voltage-resistant element requiring a relatively thick gate insulating film on a semiconductor substrate surrounded by a trench separation insulating film.

As shown in FIG. 1A, a well region 11 of a first conductive type is formed in a silicon semiconductor substrate. This well region 11 is arranged, as a high voltage-resistant well, before a trench separation region forming process to be explained later. A ground oxide film 12 including this well region 11 is formed. A wet oxidation process is used for the ground oxide film 12 and a silicon oxide film is subjected to film making for approx. 10 nm.

Next, CVD is applied to over the ground oxide film 11 to make a silicon nitride film 13 of a thickness of approx. 150 nm. This is followed by photolithography and etching to form a mask pattern MP. Thereafter, according to the mask pattern MP, the semiconductor substrate is subjected to etching and a trench 14 is formed.

Next, as shown in FIG. 1B, through the wet etching process, an edge part of the ground oxide film 12 is retreated for approx. 35 nm. Then, a surface inside the trench 14 is oxidized (broken lines) by a dry oxidation atmosphere from 1,030° C. to 1070° C., preferably at approx. 1,050° C. And to relieve stress, annealing is conducted at a temperature higher than the oxidation process referenced above, for example, 1,100° C.

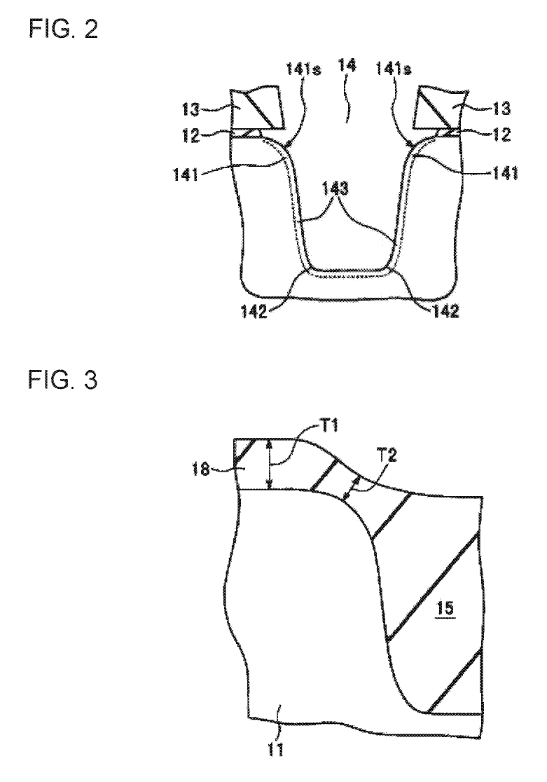

FIG. 2 shows an enlarged view of the trench section regarding FIG. 1B. By means of the above-referenced process, it is possible provide a more gentle round shape to an upper edge 141 and a bottom edge 142 at the trench 14. Particularly, the upper edge 141 assumes a shape such as to include a portion close to a gentle slope (141s) through optimum retreat control of the thickness (10 nm) of the ground oxide film 12. Furthermore, the surface inside the trench 14 is covered with a superior quality thermal oxide film 143 of high insulation where crystal defects are restrained.

Next, as shown in FIG. 1C, an insulating film 15 is embedded in the trench 14. The insulating film 15 is a film made of a plasma silicon oxide film using the high density plasma process. Subsequently, chemical and mechanical polishing (CMP) techniques are used to level out the insulating film 15. Then, the mask pattern MP is removed. Removal of the silicon nitride film 13 through thermal phosphoric acid or lift off etching from the ground oxide film 12 using hydrofluoric acid may be considered. To eliminate the ground oxide film 12 completely, wet etching using hydrofluoric acid or phosphoric ammonium is added. The surface of the insulating film 15 inside the trench 14 is also subjected to etching for a preset amount.

Next, as shown in FIG. 1D, a pre-oxide film (silicon oxide film) 16 is formed on a substrate on the well region 11. Using the wet oxidation process, it may be formed such that its thickness reaches 10 nm±0.5 nm, more preferably, 10.3 nm. This thickness was calculated in consideration of uniformity inside a wafer surface.

Now, a mask pattern not illustrated on the well region 11 is formed, and according to the mask pattern, an impurity region 17 of the second conductive type, which is an opposite conductive type to the well region 11, is formed. The impurity region 17 is a high voltage-resistant drift region, and it is subjected to ion implantation so that the depth becomes such as to cross the insulating film 15.

Next, as shown in FIG. 1E, the pre-oxide film 16 is removed by light etching using hydrofluoric ammonium and the like. At this time, it is set up such that the round shape surface of the upper part of the trench 14 is exposed. Namely, the gentle round shape surface of the upper edge 141 is exposed.

Next, as shown in FIG. 1F, a gate insulating film 18 is formed on the well region 11 in such a way that the edge part side is arranged from above the edge part of the impurity region 17 to over the edge part of the insulating film 15. The gate insulating film 18 is a silicon oxide film, approx. 65 nm thick, to be formed by the thermal oxidation process.

FIG. 3 is an enlarged view showing a status of the gate insulating film 18 of the end part of an active section regarding FIG. 1F. As a result of a gentler round shape of the edge 14 of the upper part of the trench, the quantity of supply of silicon does not drop to extremes. Hence, the gate insulating film 18 is such that its thickness T1 of the edge part side satisfies more than 70% with respect to an average thickness T1 in the vicinity of the central part.

Next, as shown in FIG. 1G, a gate electrode 19 is formed on the gate insulating film 18. Namely, the CVD is used to deposit a polysilicon layer, and after the photolithography process, it is subjected to patterning. Thereafter, inside the impurity region 17 with a gate electrode 19 in between, a source diffusion layer 21 and a drain diffusion layer 22 of the second conductive type, which are respectively in higher concentration than the impurity region 17, may be formed.

According to a process of the embodiment described above which is the high voltage-resistant element, the retreat of the ground oxide film 12 through the wet etching process affects a change in shape of the upper edge 141 in the trench 14. Consequently, the thickness of the ground oxide film 12 is critical as well.

In this embodiment, optimization was made at 10 nm. Further, when oxidizing the surface inside the trench 14, a superior quality insulator is formed by oxidizing at a temperature exceeding 1,000° C. Further, by performing the annealing process at a temperature higher than this oxidation process, contribution is made for relieving stress as well as preventing crystal defects.

Moreover, the pre-oxide film 16 is made to be thin enough to make it controllable for enhancing uniformity in the surface. In the embodiment, optimization is made by setting the thickness at 10 nm±0.5 nm, more preferably, 10.3 nm. If the pre-oxide film 16 is set with the same thickness as the ground oxide film, at the time of removal, control can be referred to, thus making it easy to handle.

When removing the pre-oxide film 16 completely, the round shape surface of the upper edge 141 of the trench 14 is made to be exposed by over etching. This enables supply of silicon to the upper edge part of the trench 14 to increase. At the edge part of the gate insulating film 18, its extreme tapering is eliminated to bring it to a mode close to the average thickness of the central part.

It should be pointed out that sharing a process with a logic section inside the integrated circuit is easy. The process of forming a thin film transistor maintains only trench separation configuration in the processes from FIG. 1A to FIG. 1F. Namely, at the time of high voltage-resistant type processing such as formation of a high voltage-resistant well of the well region 11, formation of a high voltage-resistant drift region of the impurity region 17, and formation of the gate insulating film 18 for high voltage resistance, measures such as masking are taken to prevent formation.

When forming the gate insulating film 18 of FIG. 1F, a gate insulating film for normal voltage resistance is formed, while, when subsequently forming the gate electrode 19 of FIG. 1G, after the photolithography process, a gate electrode for normal voltage resistance may be subjected to patterning.

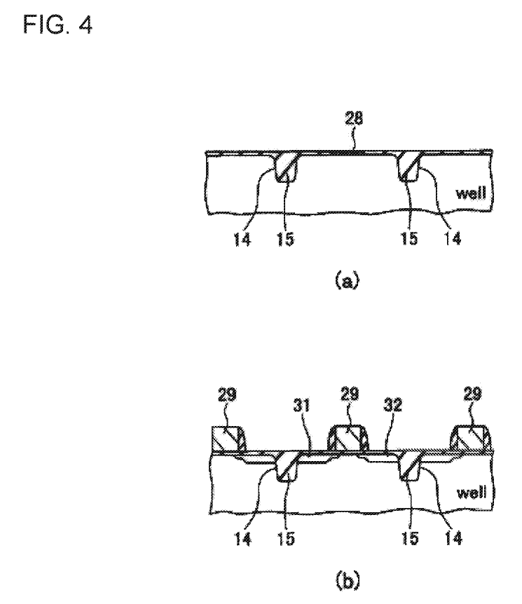

FIGS. 4A and B are sectional views respectively showing processes of forming a thin film transistor for normal voltage resistance at the logic section of the integrated circuit. FIG. 4A is carried out by partly sharing the process of FIG. 1F, while FIG. 4B is carried out by sharing the process of FIG. 1G.

In FIG. 4A, after the trench separation process is carried out, a well in the logic section is formed. Thereafter, when forming the gate insulating film 18 of FIG. 1F, part of the process is made to be shared to form a gate insulating film 28 for normal voltage resistance.

Next, as shown in FIG. 4B, the process is made to be shared when forming the gate electrode 19 of FIG. 1G, to form a gate electrode 29 for normal voltage resistance. Then, after formation of a side wall and the like, source/drain diffusion layers 31 and 32 are formed.

As described above, according to the invention, optimization of the thickness of the ground oxide film accompanying a nitride film mask and optimization of the retreat are useful, affecting the change in shape of the upper edge of the trench.

Further, when oxidizing, oxidation is carried out at a temperature over 1,000° C. to form a superior quality insulator. Even further, performing the annealing process at a high temperature contributes to relieving stress. The pre-oxide film is made thin enough to make it controllable for enhancing uniformity inside the surface. When eliminating the pre-oxide film completely, the round shape surface of the upper part of the trench is exposed. This enables supply of silicon to the upper edge part of the trench to increase. Consequently, the gate insulating film becomes such that the extreme tapering is eliminated at its edge part to bring it to a mode close to the average thickness of the central part. As a result, the preset thickness of the gate oxide film can be secured even on the end part of the active section, thereby making it possible to provide a manufacturing process of a semiconductor device and a semiconductor device to produce excellent voltage resistance.

It should be pointed out that the invention is not limited to the embodiment and processes referenced above but a variety of changes, modifications, and application within the spirit and scope of the invention can be implemented.

What is claimed is:

1. A method of manufacturing a semiconductor device comprising:
forming a ground oxide film, which includes over a well region of a first conductive type, on a silicon semiconductor substrate;
forming a nitride film over the ground oxide film;
forming a mask pattern by selectively etching the nitride film and the ground oxide film;
forming a trench by etching the semiconductor substrate according to the mask pattern;
wet etching to retreat an edge part of the ground oxide film;
oxidizing a surface inside the trench through a dry oxidation atmosphere;
annealing at a temperature higher than the oxidation;
embedding an insulating film inside the trench;
leveling out the insulating film;
removing the mask pattern;
removing a remaining film of the Bound oxide film;
forming a pre-oxide film on the semiconductor substrate;
forming on the first conductive type region an impurity region of a second conductive type with a depth crossing the insulating film;
etching to eliminate the pre-oxide film, and, at the same time, to make a round shape surface of an upper part of the trench exposed;
forming a gate insulating film on the first conductive type region such that the edge part side may be placed from over the edge part of the impurity region of the second conductive type to over the edge part of the insulating film; and
forming a gate electrode on the gate insulating film.

2. The manufacturing process of a semiconductor device according to claim 1, wherein the well region is a high voltage-resistant well region for a high voltage-resistant device and the thickness of the edge part side of the gate insulating film satisfies more than 70% with respect to the average thickness in the vicinity of the central part.

3. The semiconductor device according to claim 1, wherein the ground oxide film is formed for a target of 10 nm in film thickness.

4. The manufacturing process of a semiconductor device, comprising:
forming a first well region of the first conductive type on a silicon semiconductor substrate;
forming the ground oxide film which includes over the first well region;
forming a nitride film for a mask on the ground oxide film;
forming a mask pattern by selectively etching the nitride film and the ground oxide film;
forming a trench by etching the semiconductor substrate according to the mask pattern;
wet etching to retreat an edge part of the ground oxide film;
oxidizing a surface inside the trench through a dry oxidation atmosphere;
annealing at a temperature higher than the oxidation process;
embedding an insulating film inside the trench;
leveling out the insulating film through chemical and mechanical polishing;
removing the mask pattern;
removing a remaining film of the ground oxide film;
forming a pre-oxide film on the semiconductor substrate having a thickness of 10 nm±0.5 nm;
forming on the first conductive type region an impurity region of a second conductive type with a depth crossing the insulating film;
etching to remove completely the pre-oxide film, and at the same time, to make a round shape surface of an upper part of the trench exposed;
forming a first gate insulating film on the first conductive type region such that at least the edge part side may be placed from over the edge part of the impurity region of the second conductive type to over the edge part of the insulating film;
forming a second well region of the first conductive type or the second conductive type at a preset part of the semiconductor substrate other than the first well region;
forming a second gate insulating film with less film thickness than the first gate insulating film on the semiconductor substrate in the second well region;
forming the first gate electrode and the second gate electrode respectively on the first gate insulating film and the second gate insulating film; and
forming an impurity region of an opposite conductive type to the second well region on the semiconductor substrate on both sides of the semiconductor substrate with the second gate electrode in between.

5. The manufacturing process of a semiconductor device according to claim 4, wherein the ground oxide film is formed for a target of 10 nm in film thickness.

6. The manufacturing process of a semiconductor device according to claim 4, wherein oxidizing the surface inside the trench takes oxidation processing time to make the inside wall of the trench composed of an oxide film approximately 30 nm thick;

7. The manufacturing process of a semiconductor device according to claim 4, wherein the insulating film is a plasma silicon oxide film which is made into a film through high density plasma.

8. The manufacturing process of a semiconductor device according to claim 4, wherein the second gate insulating film is used for normal voltage resistance, while the first gate insulating film is used for high voltage resistance, an edge part side thickness of the first gate insulating film satisfying more 70% with respect to the average thickness in the vicinity of the central part.

9. A semiconductor device, comprising:
the first and the second insulating films embedded in trenches mutually set apart from each other in a well region of the first conductive type in the silicon semiconductor substrate;
a first impurity region of the second conductive type formed at a depth crossing the first insulating film on the well region and a second impurity region of the second conductive type formed with a depth crossing the second insulating film on the well region;
a gate insulating film, which includes over a channel part of a surface of the well region in between the first and the second impurity regions with its both ends connected to one edge part of the first insulating film and one edge part of the second insulating film, an edge part side thickness satisfying more than 70% with respect to an average thickness in the vicinity of the central part;
a gate electrode formed on the gate insulating film;
a source diffusion layer of the second conductive type, which is formed on the first impurity region in the vicinity of the other edge part side of the first insulating film, and a drain diffusion layer, which is formed on the second impurity region in the vicinity of the other edge part side of the second insulating film, both layers being of the second conductive type of higher concentration than the first and the second impurity regions.
